(19) United States
(12) Patent Application Publication
(10) Pub. No.: US 2025/0254817 A1
(43) Pub. Date: Aug. 7, 2025

(54) COOLING APPARATUS

(71) Applicant: Sony Group Corporation, Tokyo (JP)

(72) Inventors: Masaaki HASEGAWA, Chiba (JP); Kento TAKURA, Kanagawa (JP); Koji IZUMI, Kanagawa (JP); Masashi KOKUBO, Kanagawa (JP)

(73) Assignee: Sony Group Corporation, Tokyo (JP)

(21) Appl. No.: 18/855,115

(22) PCT Filed: Mar. 20, 2023
(86) PCT No.: PCT/JP2023/010783

§ 371 Date: Oct. 8, 2024

(30) Foreign Application Priority Data
May 2, 2022 (JP) 2022-075971

(51) Int. Cl. H05K 7/20; H04M 1/02

(52) U.S. Cl. CPC H05K 7/20145; H04M 1/0203; H05K 7/20972

(57) ABSTRACT

A cooling apparatus according to an embodiment of the present technology includes a cooling fan and a duct portion. The cooling fan is provided on a back surface of a mobile terminal that includes a display surface and the back surface situated opposite to the display surface. The duct portion is used to blow, to the display surface, air supplied from the cooling fan. This makes it possible to improve the cooling efficiency in cooling the mobile terminal without sacrificing the visibility of a display or an operation performance of an operation section including a touchscreen and keys.

### TECHNICAL FIELD

The present technology relates to a cooling apparatus that can be applied to cooling of mobile terminals such as smartphones.

### BACKGROUND ART

Patent Literature 1 discloses a portable electronic apparatus that includes a portable-electronic-apparatus body and a cradle apparatus. The portable electronic apparatus includes a heat release portion that can release heat generated by an optical disk drive when electric power is being output to a first input terminal through which the electric power is input from the cradle apparatus. This makes it possible to make the portable-electronic-apparatus body smaller in size and to record a signal on an optical disk while causing heat to be effectively generated by the optical disk drive (for example, paragraphs [0031] to [035] of the specification and FIG. 2 in Patent Literature 1).

### CITATION LIST

### Patent Literature

Patent Literature 1: Japanese Patent Application Laid-open No. 2007-213121

### DISCLOSURE OF INVENTION

### Technical Problem

There is a need for a technology that makes it possible to improve the cooling efficiency in cooling such a mobile terminal.

In view of the circumstances described above, it is an object of the present technology to provide a cooling apparatus that makes it possible to improve the cooling efficiency.

### Solution to Problem

In order to achieve the object described above, a cooling apparatus according to an embodiment of the present technology includes a cooling fan and a duct portion.

The cooling fan is provided on a back surface of a mobile terminal that includes a display surface and the back surface situated opposite to the display surface.

The duct portion is used to blow, to the display surface, air supplied from the cooling fan.

The cooling apparatus includes the cooling fan provided on a back surface of a mobile terminal that includes a display surface and the back surface situated opposite to the display surface; and the duct portion used to blow, to the display surface, air supplied from the cooling fan. This makes it possible to improve the cooling efficiency.

The duct portion may include a curved portion that covers around the display surface from the back surface and that provides directivity to the air such that the air is blown to the display surface.

The cooling apparatus may further include an insertion portion that is situated between the cooling fan and the curved portion and into which the mobile terminal is insertable. In this case, the duct portion may include a passage that leads the air from the cooling fan to the curved portion. The passage may be formed by the mobile terminal being inserted into the insertion portion.

The curved portion may be provided such that the air is blown over the display surface from at least two directions.

The curved portion may include a first curved portion that causes the air to be blown to the display surface from a first direction, and a second curved portion that causes the air to be blown to the display surface from a second direction that is different from the first direction. In this case, the duct portion may include a first passage that leads the air from the cooling fan to the first curved portion, and a second passage that leads the air from the cooling fan to the second curved portion. The first passage may have a thickness that is different from a thickness of the second passage.

The thicknesses of the first passage and the second passage may be set on the basis of a distribution of heat generated by the mobile terminal.

The duct portion may include a notch portion that does not prevent a user from performing an operation related to the mobile terminal.

The cooling apparatus may further include a diffusion plate that leads the air from the cooling fan to the passage. In this case, the diffusion plate may include a first hole that leads the air to the first passage, and a second hole that leads the air to the second passage.

The area of the first hole may be set on the basis of the thickness of the first passage. In this case, the area of the second hole may be set on the basis of the thickness of the second passage.

### BRIEF DESCRIPTION OF DRAWINGS

FIG. 1 schematically illustrates an appearance of a cooling apparatus.

FIG. 2 schematically illustrates an appearance of a diffusion plate.

FIG. 3 schematically illustrates an appearance of a notch portion.

FIG. 4 schematically illustrates flow of air intaken by a cooling fan.

FIG. 5 schematically illustrates simulations for different shapes of models of mobile terminals.

FIG. 6 schematically illustrates airflows in the mobile terminals of the respective models.

### MODE(S) FOR CARRYING OUT THE INVENTION

Embodiments according to the present technology will now be described below with reference to the drawings.

### [Appearance of Cooling Apparatus]

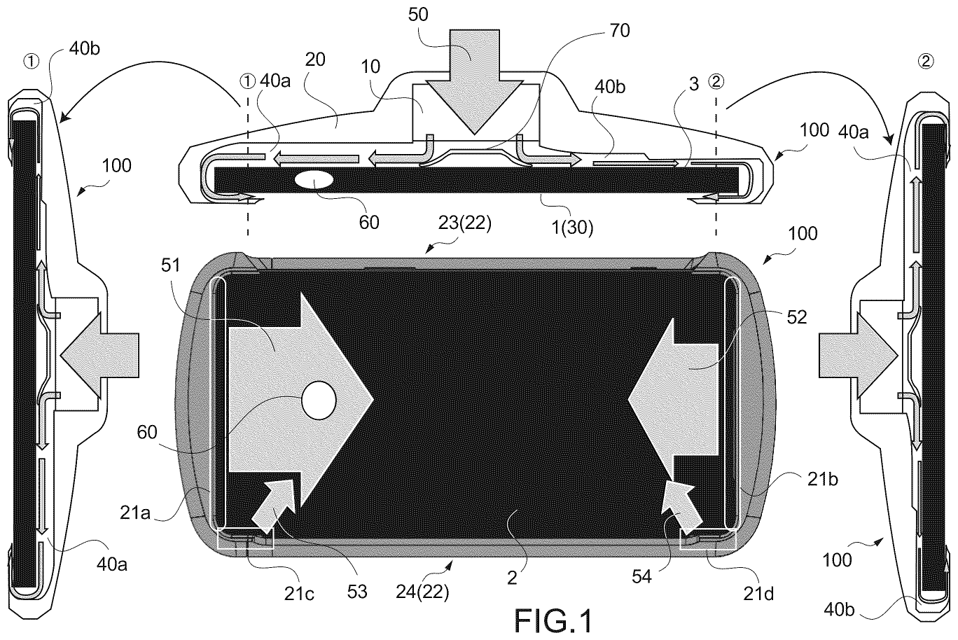

FIG. 1 schematically illustrates an appearance of a cooling apparatus 100 according to the present technology.

In the present embodiment, the cooling apparatus 100 is an apparatus used to cool a mobile terminal 1 such as a smartphone or a tablet. Further, in the present embodiment, the mobile terminal 1 is assumed to be in a state in which game content is used on a laterally long screen. In other words, a user holds short sides of the mobile terminal (a first curved portion 21a and a second curved portion 21b that will be described later), and touches a display surface 2 to perform operation.

As illustrated in FIG. 1, the cooling apparatus 100 includes a cooling fan 10, a duct portion 20, and an insertion portion 30.

The cooling fan 10 is provided on a back surface 3 of the mobile terminal 1 that is situated opposite to the display surface 2. The cooling fan 10 intakes surrounding air to supply the air to the duct portion 20. Note that a place at which the cooling fan 10 is provided is not limited. For example, the cooling fan 10 may be provided at any place on the back surface 3 according to a distribution of heat generated by the mobile terminal 1 or portions of the mobile terminal 1 that are held by a user with his/her hands. Further, not only the cooling fan 10 but also, for example, a Peltier element that cools supplied air may be provided.

The duct portion 20 blows, to the display surface 2, air supplied from the cooling fan 10. In the present embodiment, the duct portion 20 includes a curved portion 21 and a notch portion 22.

The insertion portion 30 is situated between the cooling fan 10 and the curved portion 21, and the mobile terminal 1 can be inserted into the insertion portion 30. In the present embodiment, the insertion portion 30 is a cavity (a concave) that has a shape dependent on a shape of the mobile terminal 1 and is formed by the duct portion 20 that includes the curved portion 21. The mobile terminal 1 inserted into the insertion portion 30 is held by the curved portion 21. A method for inserting the mobile terminal 1 into the insertion portion 30 is not limited. The curved portion 21 may be an elastic body such as rubber, or the mobile terminal 1 may be slid to be inserted due to the first curved portion 21a or the second curved portion 21b being removable.

In the present embodiment, the mobile terminal 1 is inserted into the insertion portion 30 to form a passage 40 that leads air from the cooling fan 10 to the curved portion 21. Further, in the present embodiment, the passage 40 branches into two passages in two directions parallel to a direction in which a long side of the mobile terminal 1 extends. In other words, air supplied from the cooling fan 10 splits into two airflows along two passages 40 (a first passage 40a and a second passage 40b), and air is blown to the display surface 2 from each of the different directions.

The curved portion 21 covers around the display surface 2 from the back surface 3, and provides directivity to air such that the air is blown to the display surface 2. In the present embodiment, the curved portion 21 is U-shaped. As illustrated in FIG. 1, flow of air (refer to an arrow 50) that is intaken from the cooling fan 10 to be led by the passage 40 is curved by the curved portion 21 to be blown to the display surface 2.

In the present embodiment, the curved portion 21 is provided such that air is blown over the display surface 2 from at least two directions. As illustrated in FIG. 1, the curved portion 21 includes the first curved portion 21a causing air to be blown to the display surface 2 from a first direction 51, the second curved portion 21b causing air to be blown to the display surface 2 from a second direction 52, a third curved portion 21c that causes air to be blown to the display surface 2 from a third direction 53, and a fourth curved portion 21d that causes air to be blown to the display surface 2 from a fourth direction 54.

The first curved portion 21a and the third curved portion 21c each cause air led by the first passage 40a to be blown to the display surface 2. The second curved portion 21b and the fourth curved portion 21d each cause air led by the second passage 40b to be blown to the display surface 2.

In FIG. 1, it is assumed that a heat generation spot 60 that represents a place at which an amount of heat generated by the mobile terminal 1 is largest, is situated near the first curved portion 21a and the third curved portion 21c. Thus, in the present embodiment, the cross-sectional area of the first passage 40a is set larger than the cross-sectional area of the second passage 40b such that a larger volume of airflow passes through the first passage 40a.

As described above, an airflow volume can be regulated according to the cross-sectional area (a thickness) of a passage. In the present embodiment, the cross-sectional area of a passage is set as appropriate according to a distribution of heat generated by the mobile terminal 1. Note that the cross-sectional area of a passage may be designed discretionarily according to a heat generation spot of heat generated due to the type of the mobile terminal 1 or due to content, or the cross-sectional area of a passage may be adjusted by partially closing the passage using, for example, a flap.

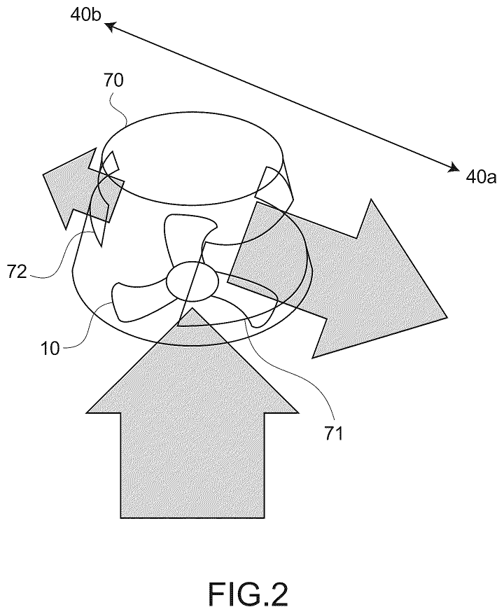

Further, a method for regulating an airflow volume is not limited, and a diffusion plate 70 illustrated in FIGS. 1 and 2 may be provided in addition to the adjustment of the cross-sectional area of a passage. For example, the diffusion plate 70 may have a shape of a frustum of a cone, and a first hole 71 and a second hole 72 may be respectively provided in a direction in which the first passage 40a extends and in a direction in which the second passage 40b extends, as illustrated in FIG. 2. For example, an airflow volume may be regulated by making the area of the first hole 71 facing the first passage 40a larger than the area of the second hole 72. In other words, the area of the first hole 71 and the area of the second hole 72 may be respectively set on the basis of a thickness of the first passage 40a and on the basis of a thickness of the second passage 40b. Note that a shape of the diffusion plate 70 is not limited, and the diffusion plate 70 shaped and sized discretionarily may be provided.

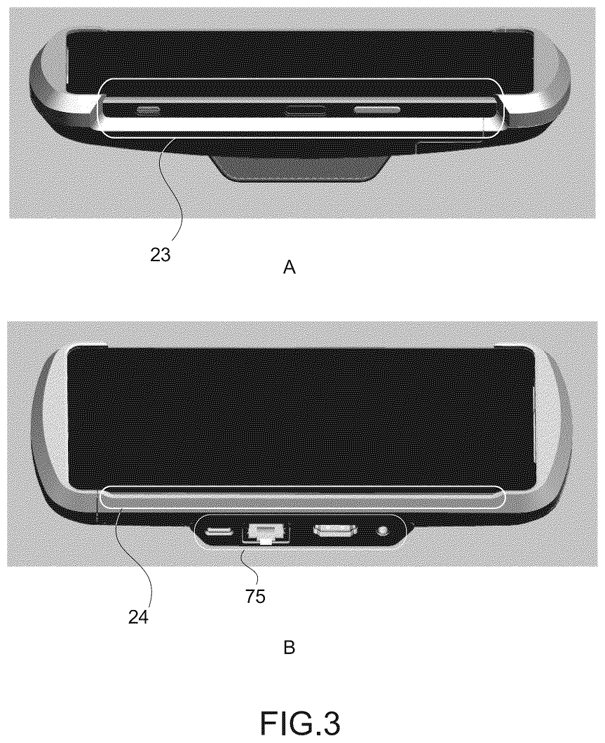

The notch portion 22 is provided in order not to prevent a user from performing an operation related to the mobile terminal 1. For example, the notch portion 22 (hereinafter referred to as a first notch portion 23) corresponding to one of the long sides of the mobile terminal 1 is provided in order not to prevent, for example, a button, a microphone, a camera, and a terminal of the mobile terminal 1 from being used (refer to A of FIG. 3). In the present embodiment, another of the notch portions 22 (hereinafter referred to as a second notch portion 24) is provided in order not to prevent a user from performing an operation related to the mobile terminal 1, especially an operation related to game content (refer to B of FIG. 3).

As illustrated in B of FIG. 3, the height of the second notch portion 24 is set smaller than each of the height of the third curved portion 21c and the height of the fourth curved portion 21d. Typically, a shape that provides interference avoidance is adopted as a shape of the second notch portion 24 such that the second notch portion 24 has a height smaller than or equal to the height of the display surface 2 of the mobile terminal 1.

This results in not preventing a user from performing an operation of touching the display surface 2 with his/her thumb while the user is playing game content. In other words, designing is performed in order not to interrupt an operation performed on a user interface (UI) displayed on a lower edge portion of the display surface 2 (on an edge portion of a screen). In addition, operation performed by a user is also not prevented when, for example, a seek bar displayed while the user is viewing a video is displayed on the lower edge portion of the display surface 2.

Note that there may be further various options for the configuration of the cooling apparatus 100 in addition to the description above. For example, a functionality expansion section 75 that includes accessories such as a USB, a LAN, HDMI, and an audio jack may be provided to the cooling apparatus 100 to extend in a direction parallel to a direction in which a long side of the cooling apparatus 100 that includes the second notch portion 24 extends, as illustrated in B of FIG. 3. A position of the functionality expansion section 75 is not limited. When the functionality expansion section 75 is provided to extend in a direction parallel to a direction in which the second notch portion 24 extends, a cable connected to the functionality expansion section 75 does not prevent a user from performing operation and the cable does not disturb, due to its weight, the user who is holding the mobile terminal 1 in the case in which the mobile terminal 1 is used in a state of being held to be long sideways, as in the present embodiment.

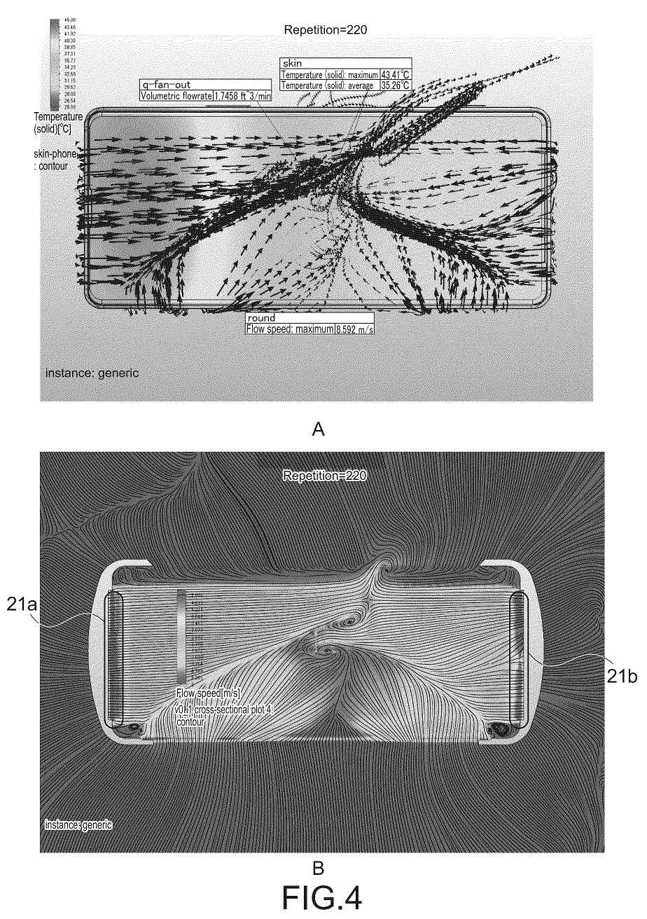

FIG. 4 schematically illustrates flow of air intaken by the cooling fan 10.

A of FIG. 4 illustrates an airflow volume and a temperature of the mobile terminal 1. B of FIG. 4 illustrates an airflow speed.

In A of FIG. 4, a position that indicates a heat generation spot of the mobile terminal 1 is displayed in a dark color. As illustrated in FIG. 1, the first passage 40a leading air to each of the first curved portion 21a and the third curved portion 21c is thicker than the second passage 40b. Thus, a greater volume of airflow (a larger number of arrows) passes over the heat generation spot.

For example, when a volumetric flowrate is 1.7458 [ft\hat{ }3/min] and a maximum airflow speed is 8.592 [m/s], a highest temperature (a temperature near the heat generation spot) on the surface of the mobile terminal 1 is 43.41° C., and an average temperature on the surface of the mobile terminal 1 is 35.26° C. in A of FIG. 4. In other words, the provision of the curved portion 21 results in cooling the mobile terminal 1 efficiently. Of course, to what extent the mobile terminal 1 is cooled differs depending on, for example, a value of the volumetric flowrate or airflow speed, or a position or shape of the curved portion 21.

As illustrated in B of FIG. 4, the airflow speed is highest near the first curved portion 21a and the second curved portion 21b, and air is blown to the entirety of the display surface 2. Air is blown over the surface of the display surface 2, as described above, and, for example, this makes it possible to prevent the hand from getting sweaty and to slide the finger smoothly.

As described above, control performed on a space between the duct portion 20 and the mobile terminal 1 (a housing) is important in order to maximize an effect of heat release from the mobile terminal 1.

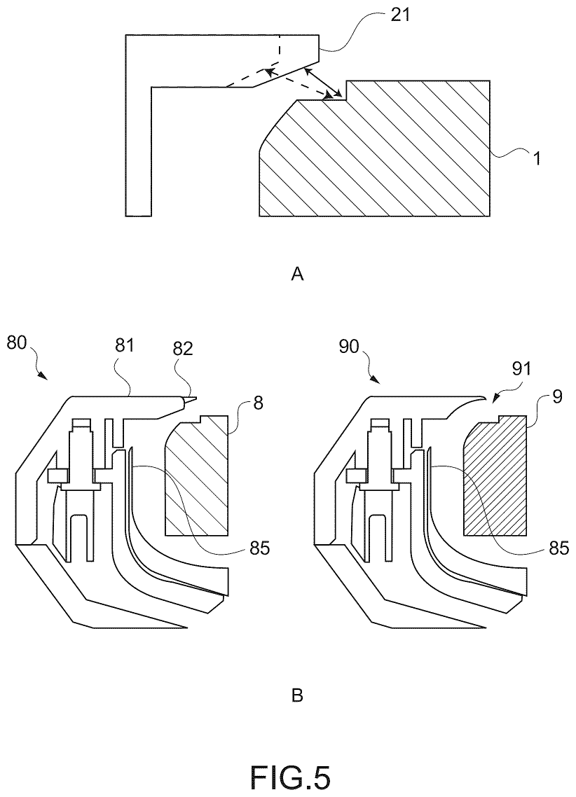

For example, when a space between the curved portion 21 and the mobile terminal 1 (an outlet out of which wind comes) is too small, this results in reducing the airflow volume, and when the space between curved portion 21 and the mobile terminal 1 is too large, this results in decreasing the airflow speed (refer to A of FIG. 5). In particular, the size of the mobile terminal 1 differs depending on the model. Thus, a cooling apparatus that provides an appropriate effect for a specific model may fail to satisfy heat releasing properties for another model due to there being a difference in airflow volume or airflow speed.

Further, with respect to mobile terminals of different models, especially mobile terminals of different thicknesses (mobile terminals of different lengths in a direction vertical to the display surface 2), passages respectively formed by the mobile terminals each being inserted into the cooling apparatus 100 have different cross-sectional areas.

It is conceivable that an opening rate of an outlet for a display surface could be increased by moving a cover (a curved portion) by 1 mm, in order to take effective measures against such a difference in heat releasing properties that is caused due to a difference in model.

FIG. 5 schematically illustrates simulations for different shapes of models of the mobile terminals 1. A of FIG. 5 schematically illustrates the space between the curved portion 21 and the mobile terminal 1. B of FIG. 5 schematically illustrates two mobile terminals of different models and respective cooling apparatuses.

As illustrated on the left in B of FIG. 5, a curved portion 81 of a cooling apparatus 80 into which a mobile terminal 8 of a specific model (hereinafter referred to as a model (a)) is inserted includes an eaves portion 82 used to increase an opening rate of an outlet for a display surface. In the present embodiment, an opening between the cooling apparatus 80 and the mobile terminal 8 is increased by 0.3 mm, and the eaves portion 82 enables the curved portion of the cooling apparatus 80 to have a length 1 mm greater than a curved portion of a cooling apparatus 90 described later.

As illustrated on the right in B of FIG. 5, a mobile terminal 9 of a model (hereinafter referred to as a model (b)) that is different from the model (a) is inserted into the cooling apparatus 90. In the present embodiment, the cooling apparatus 90 is adjusted such that an outlet 91 has a size of 1.16 mm.

Further, a slope component 85 included in each of the cooling apparatus 80 and the cooling apparatus 90 is made thinner by 1 mm according to the cover moved by 1 mm.

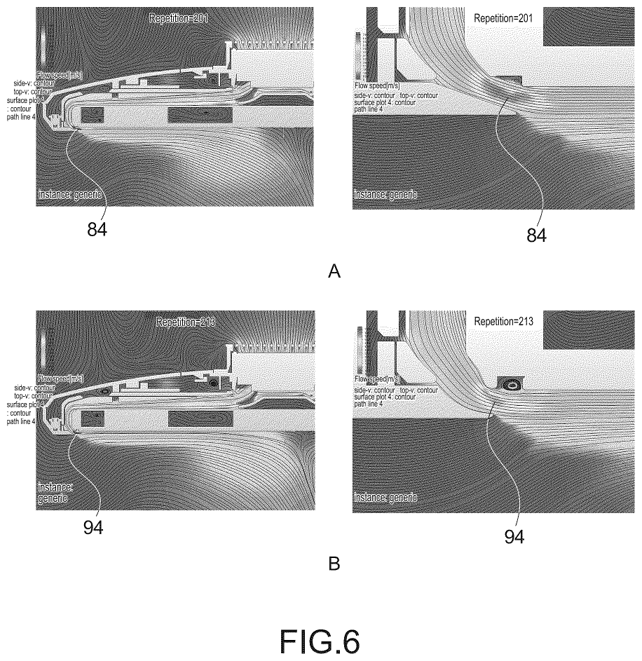

FIG. 6 schematically illustrates airflows in the mobile terminals of the respective models. A of FIG. 6 schematically illustrates the airflow in the model (a). B of FIG. 6 schematically illustrates the airflow in the model (b).

Air blown from an outlet 84 and air blown from an outlet 94 can also be caused to exhibit the same airflow volume and the same airflow speed when mobile terminals have different shapes, as illustrated in FIG. 6 (refer to the right side in A of FIG. 6 and the right side in B of FIG. 6).

As described above, the cooling apparatus 100 according to the present embodiment includes the cooling fan 10 provided on the back surface 3 of the mobile terminal 1 including the display surface 2 and the back surface 3 situated opposite to the display surface 2, and the duct portion 20 used to blow, to the display surface 2, air supplied from the cooling fan 10. This makes it possible to improve the cooling efficiency.

Conventionally, there are two kinds of structures used to cool mobile terminals: a structure in which heat generated by a mobile terminal is concentrated into a cooling section, and a structure in which the thermal conductivity is increased such that partial cooling of a mobile terminal results in providing a cooling effect to the entirety of the mobile terminal. Further, in general, thermal design of a mobile terminal including no external cooling apparatus prevents heat from being concentrated locally and diffuses heat throughout the terminal to increase the thermal capacity. However, the concentration of heat onto a single spot results in significant heat-related restrictions such as low-temperature burn when a cooling apparatus is not used. Further, cooling of a partial portion results in there being a need to decrease the thermal conductivity on a front surface since the thermal conductivity on a back surface is high.

According to the present technology, a cooling source and a duct structure that entirely circulates air from the cooling source are provided to a portion to which the provision does not affect operation performed by a user, and the air is released to a portion that is included in an operation section and to which the duct structure is not allowed to be applied. This makes it possible to cool all of the surfaces of a mobile terminal without sacrificing the visibility of a display or an operation performance of the operation section including a touchscreen and keys.

### OTHER EMBODIMENTS

The present technology is not limited to the embodiments described above, and can achieve various other embodiments.

In the embodiments described above, it is assumed that a user uses the mobile terminal 1 in a state in which one of the long sides of the mobile terminal 1 is situated at a lower position, in order to play game content. Without being limited thereto, the game content may be operated in a state in which one of the short sides of the mobile terminal 1 is situated at a lower position, that is, the game content may be operated on a longitudinally long screen. In this case, the curved portion 21 and the notch portion 22 are provided on the basis of, for example, a position of the hand of the user who is holding the mobile terminal 1, or a position of the fingers of the user who is operating the mobile terminal 1. For example, the curved portion 21 may be provided to each of three sides other than a side held by the user.

In the embodiments described above, the notch portion 22 is provided in order not to decrease a performance of operation performed by a user. Without being limited thereto, the notch portion 22 does not necessarily have to be provided, in order to improve the cooling efficiency in cooling the mobile terminal 1. For example, the first notch portion 23 may be replaced with the curved portion 22 on the assumption that an operation using a button is not performed during using game content. In other words, at least one of, for example, a button, a microphone, a camera, or a terminal may be covered with the curved portion 22 to improve the cooling performance. For example, the first notch portion 23 may be provided such that a camera and a terminal are covered with the first notch portion 23 and a button and a microphone are exposed. This is a modification of the first notch portion 23.

Note that the effects described in the present disclosure are not limitative but are merely illustrative, and other effects may be provided. The above description of the plurality of effects does not necessarily mean that the plurality of effects is provided at the same time. The above description means that at least one of the effects described above is provided depending on, for example, a condition. Of course, there is a possibility that an effect that is not described in the present disclosure will be provided.

At least two of the features of the respective embodiments described above can also be combined. In other words, the various features described in the respective embodiments may be combined discretionarily regardless of the embodiments.

Note that the present technology may also take the following configurations.

(1) A cooling apparatus, including:
a cooling fan that is provided on a back surface of a mobile terminal that includes a display surface and the back surface situated opposite to the display surface; and
a duct portion that is used to blow, to the display surface, air supplied from the cooling fan.
   (2) The cooling apparatus according to (1), in which
the duct portion includes a curved portion that covers around the display surface from the back surface and that provides directivity to the air such that the air is blown to the display surface.
   (3) The cooling apparatus according to (2), further including
an insertion portion that is situated between the cooling fan and the curved portion and into which the mobile terminal is insertable, in which
the duct portion includes a passage that leads the air from the cooling fan to the curved portion, and
the passage is formed by the mobile terminal being inserted into the insertion portion.
   (4) The cooling apparatus according to (2), in which
the curved portion is provided such that the air is blown over the display surface from at least two directions.
   (5) The cooling apparatus according to (4), in which
the curved portion includes
   a first curved portion that causes the air to be blown to the display surface from a first direction, and
   a second curved portion that causes the air to be blown to the display surface from a second direction that is different from the first direction,
the duct portion includes
   a first passage that leads the air from the cooling fan to the first curved portion, and
   a second passage that leads the air from the cooling fan to the second curved portion, and
the first passage has a thickness that is different from a thickness of the second passage.
   (6) The cooling apparatus according to (5), in which
the thicknesses of the first passage and the second passage are set on the basis of a distribution of heat generated by the mobile terminal.
   (7) The cooling apparatus according to (2), in which
the duct portion includes a notch portion that does not prevent a user from performing an operation related to the mobile terminal.
   (8) The cooling apparatus according to (5), further including
a diffusion plate that leads the air from the cooling fan to the passage,
the diffusion plate including
   a first hole that leads the air to the first passage, and
   a second hole that leads the air to the second passage.
      (9) The cooling apparatus according to (8), in which
the area of the first hole is set on the basis of the thickness of the first passage, and
the area of the second hole is set on the basis of the thickness of the second passage.

### REFERENCE SIGNS LIST

1 mobile terminal
2 display surface
3 back surface
10 cooling fan
20 duct portion
21 curved portion
22 notch portion
30 insertion portion
40 passage
100 cooling apparatus

1. A cooling apparatus, comprising:
a cooling fan that is provided on a back surface of a mobile terminal that includes a display surface and the back surface situated opposite to the display surface; and
a duct portion that is used to blow, to the display surface, air supplied from the cooling fan.

2. The cooling apparatus according to claim 1, wherein
the duct portion includes a curved portion that covers around the display surface from the back surface and that provides directivity to the air such that the air is blown to the display surface.

3. The cooling apparatus according to claim 2, further comprising
an insertion portion that is situated between the cooling fan and the curved portion and into which the mobile terminal is insertable, wherein
the duct portion includes a passage that leads the air from the cooling fan to the curved portion, and
the passage is formed by the mobile terminal being inserted into the insertion portion.

4. The cooling apparatus according to claim 2, wherein
the curved portion is provided such that the air is blown over the display surface from at least two directions.

5. The cooling apparatus according to claim 4, wherein
the curved portion includes
a first curved portion that causes the air to be blown to the display surface from a first direction, and
a second curved portion that causes the air to be blown to the display surface from a second direction that is different from the first direction,
the duct portion includes
a first passage that leads the air from the cooling fan to the first curved portion, and
a second passage that leads the air from the cooling fan to the second curved portion, and
the first passage has a thickness that is different from a thickness of the second passage.

6. The cooling apparatus according to claim 5, wherein
the thicknesses of the first passage and the second passage are set on a basis of a distribution of heat generated by the mobile terminal.

7. The cooling apparatus according to claim 2, wherein
the duct portion includes a notch portion that does not prevent a user from performing an operation related to the mobile terminal.

8. The cooling apparatus according to claim 5, further comprising
a diffusion plate that leads the air from the cooling fan to the passage,
the diffusion plate including
a first hole that leads the air to the first passage, and
a second hole that leads the air to the second passage.

9. The cooling apparatus according to claim 8, wherein
the area of the first hole is set on a basis of the thickness of the first passage, and
the area of the second hole is set on a basis of the thickness of the second passage.
